(19) United States
(12) Patent Application Publication
(10) Pub. No.: US 2006/0289885 A1
(43) Pub. Date: Dec. 28, 2006

(54) Light-emitting diode

(75) Inventors: Shi-Ming Chen, Tainan (TW); Chia-Yu Chang, Tainan City (TW)

Correspondence Address: SUGHRUE MION, PLLC, 2100 PENNSYLVANIA AVENUE, N.W., SUITE 800, WASHINGTON, DC, 20037, US

(73) Assignees: Shi-Ming Chen; Epitech Technology Corporation

(21) Appl. No.: 11/216,028

(22) Filed: Sep. 1, 2005

(30) Foreign Application Priority Data
Jun. 24, 2005 (TW) 94121284

(51) Int. Cl. H01L 33/00

(52) U.S. Cl. 257/98

(57) ABSTRACT

A light-emitting diode (LED) is described. The light-emitting diode has a light-emitting diode chip and a package structure covering the light-emitting diode chip. A surface of the package structure has a pattern structure, in which the pattern structure includes a plurality of stria structures for controlling a light shape output by the light-emitting diode.

### RELATED APPLICATIONS

The present application is based on, and claims priority from, Taiwan Application Serial Number 94121284, filed Jun. 24, 2005, the disclosure of which is hereby incorporated by reference herein in its entirety.

### FIELD OF THE INVENTION

The present invention relates to a light-emitting diode (LED) and applications thereof, and more particularly, to a light-emitting diode package structure having a surface pattern structure.

### BACKGROUND OF THE INVENTION

After packaging, the whole surface of a package structure of a conventional light-emitting diode is typically smooth or neat, so that a light shape is almost circular or elliptical. FIGS. 1 and 2 illustrate schematic diagrams of two different conventional light-emitting diode structures. A light-emitting diode 100 is mainly composed of a light-emitting diode chip 102 and a package structure 104 covering the light-emitting diode chip 102, such as shown in FIG. 1. A surface 106 of the package structure 104 is a smooth, curved surface. Light 108 produced by the light-emitting diode chip 102 passes through the package structure 104 to be emitted from the surface 106 of the package structure 104.

As shown in FIG. 2, a light-emitting diode 200 is mainly composed of a light-emitting diode chip 202 and a package structure 204 covering the light-emitting diode chip 202. Similarly, a surface 206 of the package structure 204 is a smooth, curved surface. Light 208 produced by the light-emitting diode chip 202 passes through the package structure 204 to be emitted from the surface 206 of the package structure 204. Because the facade of the package structure 104 is a smooth arc, and the surface 206 of the package structure 204 is a smooth semicircle, the light shapes output by the light-emitting diode 100 and the light-emitting diode 200 are divergent, and are nearly circular or elliptical.

However, in some applications, such as a lamp and an illumination structure, the conventional light-emitting diode having a circular or elliptical light shape may need a secondary optic technique for achieving the application requirements. For example, the light-emitting diode does not conform to the requirements of lamp, because the light shape output by the current light-emitting diode is divergent, and the brightness cannot be concentrated. Even if a lamp implement is used to collect light, it is difficult for the current light-emitting diode to achieve the brightness requirement of the lamp. Accordingly, when the conventional light-emitting diode is applied in a lamp module, the brightness of the original light-emitting diode chip and the amount of the light-emitting diode chips need to be increased. The cost of the lamp mold is thereby increased, making the finished product expensive, and unpopular. Moreover, the lamp mold can easily several hundred thousand U.S. dollars. A failed mold design thus involves a huge financial loss.

### SUMMARY OF THE INVENTION

Therefore, one objective of the present invention is to provide a light-emitting diode, in which a package structure of the light-emitting diode has a surface pattern structure for modifying the light shape and improving the intensity distribution of light. The present invention is suitable for applications, for example, a lamp, and can greatly reduce the cost of peripheral resources.

Another objective of the present invention is to provide a light-emitting diode suitable for a lamp. By forming at least one concave stria or at least one convex stria in a package surface of the light-emitting diode chip with a mold design, the brightness of the spotlight in the light shape can be increased, which can overcome the bottleneck of the current light-emitting diode lamp module. Accordingly, in the application of the present light-emitting diode, the amount of light-emitting diodes can be decreased, and the application requirement can be met because the brightness of the light-emitting diode chip does not need to be increased.

Still another objective of the present invention is to provide a light-emitting diode suitable for a lamp module. By forming a pattern structure in the package surface in the package process, the light shape can be modified to suit application in a lamp. Moreover, with the change of the light shape resulting from the package structure of the light-emitting diode, failure and defects of the lamp design can be recovered.

According to the aforementioned objectives, the present invention provides a light-emitting diode, comprising a light-emitting diode chip and a package structure. The package structure covers the light-emitting diode chip, in which the a surface of the package structure has a pattern structure, and the pattern structure includes a plurality of stria structures to make a light shape of the light-emitting diode be different from that of the light-emitting diode chip.

According to a preferred embodiment of the present invention, the stria structures may be concave strias, convex strias or any combination thereof. The stria structures may be substantially parallel or interlaced, and may be symmetrically or asymmetrically distributed in the surface of the package structure.

By forming at least one stria structure in the surface of the package structure, the light-output distribution shape and the light intensity distribution of the light-emitting diode chip can be modified, and the spotlight intensity in the light shape can be enhanced. Therefore, the light-emitting diode of the present invention is very suitable for the lamp module, and the light-emitting diode chip can be adjusted and controlled easily according to the lamp enactment. Failures and defects of the lamp can thus be recovered, which can effectively reduce the cost of the lamp module.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates a schematic diagram of a conventional light-emitting diode structure;

FIG. 2 illustrates a schematic diagram of a conventional light-emitting diode structure;

FIG. 3 illustrates a three-dimensional schematic diagram of a light-emitting diode in accordance with a preferred embodiment of the present invention; and

FIG. 4 illustrates a cross-sectional view of a light-emitting diode in accordance with a preferred embodiment of the present invention.

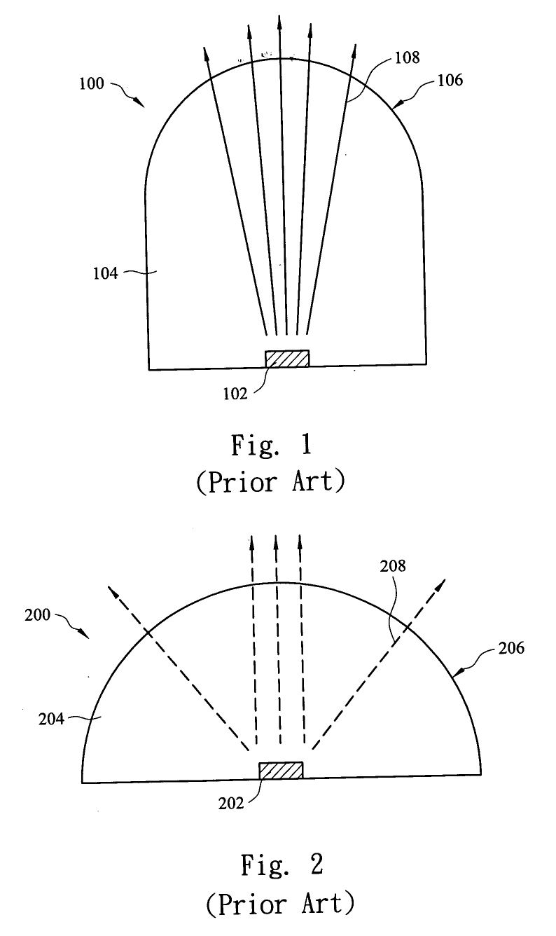

### DETAILED DESCRIPTION OF THE PREFERRED EMBODIMENT

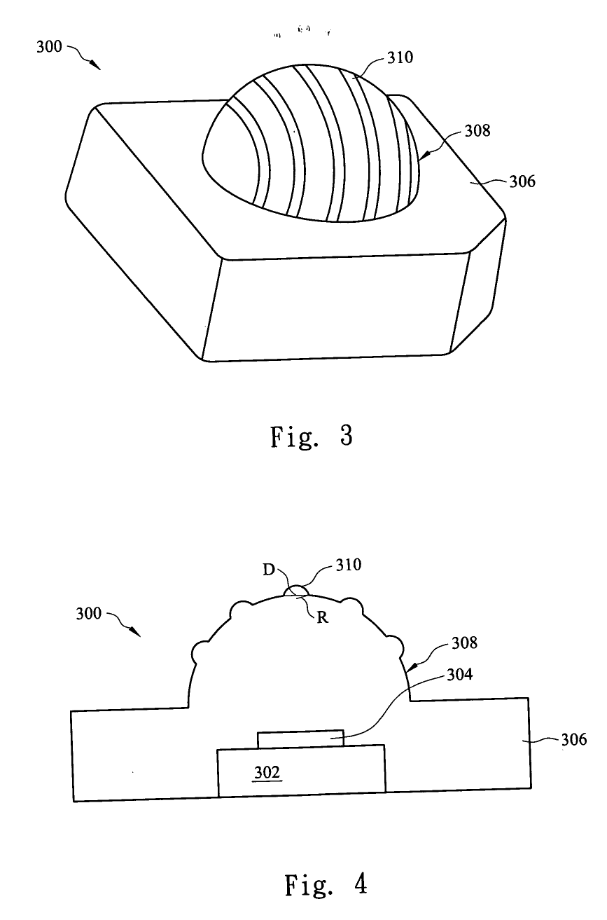

The present invention discloses a light-emitting diode, in which a surface of a package structure of the light-emitting diode is protrudingly or indentedly set with at least one stria structure. Light output distribution shape and the intensity distribution of light can thereby be controlled for achieving the requirements in the application of a lamp or illumination structure. In order to make the illustration of the present invention more explicit and complete, the following description is stated with reference to FIGS. 3 and 4.

FIG. 3 illustrates a three-dimensional schematic diagram of a light-emitting diode in accordance with a preferred embodiment of the present invention. A light-emitting diode 300 of the present invention is mainly composed of a light-emitting diode chip 304 and a package structure 306. The light-emitting diode chip 304 is deposited on a carrier 302, and then is covered by the package structure 306. The package structure 306 is composed of a package material, in which the package material is translucent or transparent, and is preferably epoxy, silicone or glass, which is pervious to the light emitted by the light-emitting diode chip 304.

In a preferred embodiment of the present invention, the package structure 306 is formed in a mold (not shown) with a required pattern for the package structure 306. The mold is infused with the package material, so as to form the package structure 306 covering the light-emitting diode chip 304, as shown in FIG. 3. In the present invention, a pattern structure may be formed in a surface 308 of the package structure 306 according to the application requirements. The pattern structure includes at least one stria structure 310. The stria structure 310 may be a concave stria, a convex stria or any combination thereof. In application, a plurality of stria structures 310 are typically set in the surface 308 of the package structure 306. In the present embodiment, the stria structures 310 in the surface 308 of the package structure 306 include five convex strias, in which the convex strias are parallel or approximately parallel to each other. By adjusting an inner radius R, a section width D, and the ratio of the inner radius R and the section width D of each convex stria, the light-output distribution shape and the intensity distribution of light produced by the light-emitting diode 300 can be effectively modified. In the present preferred embodiment, the inner radiuses R of the convex strias are respectively 0.6 mm, 0.8 mm, 1.0 mm, 0.8 mm and 0.6 mm from left to right, as shown in FIG. 4.

In other embodiments of the present invention, the stria structures 310 may be concave strias, convex strias or any combination of the concave strias and the convex strias. According to the practical application requirements, the stria structures 310 may be substantially parallel or interlaced for achieving the required light shape. In some embodiments, the stria structures 310 may be symmetrically distributed in the surface 308 of the package structure 306; while in other embodiments, the stria structures 310 may be asymmetrically distributed in the surface 308 of the package structure 306. A section of each stria structure 310 may be a curve or a polygonal curve. Besides, the package structure 306 may be formed by covering the light-emitting diode chip 304 with a layer of package material, and then performing an etching step or extra work on the surface of the package material layer to fabricate the required stria structures 310, so as to form the package structure 306 having the surface 308 including a pattern structure.

Accordingly, one feature of the present invention is that the surface of the present light-emitting diode is set with at least one stripe concave stria or at least one stripe convex stria by a mold design, an etching method or other processes, which can improve the light shape and the light intensity distribution of the light-emitting diode. Therefore, the present light-emitting diode has a very wide application. For example, by designing the surface of the package structure of the light-emitting diode in the present invention, a light shape conforming to the lamp enactment can be produced, which can greatly reduce the cost of cooperative peripheral resources, such as a reflective surface device.

In the present invention, by designing the light-emitting diode chip with different light shapes, it is tested and verified that the spotlight brightness in the light shape can have a more than 50% increase, which can overcome the bottleneck of the light-emitting diode lamp module. Accordingly, when the present light-emitting diode is applied in the lamp module, the amount of the light-emitting diodes can be decreased, and the application requirement can be met because the brightness of the light-emitting diode chip does not need to be increased. Furthermore, the light shape of the present light-emitting diode may be designed as square, rectangle or rhombus for the lamp. Moreover, because the light shape output by the light-emitting diode of the present invention can be modified by design of the package structure to enhance the spotlight brightness in the light shape, even if the design of the lamp fails, with the application of the present light-emitting diode, the failure and the defect of the lamp design can be recovered.

According to the aforementioned description, one advantage of the light-emitting diode of the present invention is that a package structure of the light-emitting diode has a surface pattern structure, which can modify the light shape and can improve the intensity distribution of light. Therefore, according to the requirements of applications, such as the lamp, the surface pattern structure of the package structure can be easily designed. The application scope of the light-emitting diode can thereby be greatly expanded, and can reduce the cost of peripheral resources.

According to the aforementioned description, another advantage of the light-emitting diode of the present invention is that by forming at least one concave stria or at least one convex stria in a package surface of the light-emitting diode chip with a mold design, the brightness of the spotlight in the light shape can be increased, so that the present light-emitting diode is very suitable for a lamp module. Therefore, in the application of the present light-emitting diode, the amount of light-emitting diodes can be decreased, and the brightness of the light-emitting diode chip does not need to be increased, which can overcome the bottleneck of the current light-emitting diode lamp module.

According to the aforementioned description, a further advantage of the light-emitting diode of the present invention is that by forming a pattern structure in the package surface in the package process, the light shape can be modified to meet lamp or illumination requirements, and the failure and the defect of the lamp design can be recovered.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A light-emitting diode, comprising:
a light-emitting diode chip; and
a package structure covering the light-emitting diode chip, wherein a surface of the package structure has a pattern structure, and the pattern structure includes at least one concave stria for controlling a light shape output by the light-emitting diode.

2. The light-emitting diode according to claim 1, wherein the package structure is composed of a translucent material or a transparent material.

3. The light-emitting diode according to claim 1, wherein a material of the package structure is selected from the group consisting of epoxy, silicone and glass.

4. The light-emitting diode according to claim 1, wherein the pattern structure is an etched pattern structure.

5. The light-emitting diode according to claim 1, wherein the pattern structure is a mold-formed pattern structure.

6. The light-emitting diode according to claim 1, wherein a section of the at least one concave stria is a curve or a polygonal curve.

7. The light-emitting diode according to claim 1, wherein the pattern structure further includes at least one convex stria.

8. The light-emitting diode according to claim 7, wherein a section of the at least one convex stria is a curve or a polygonal curve.

9. The light-emitting diode according to claim 7, wherein the at least one concave stria and the at least one convex stria are substantially parallel.

10. The light-emitting diode according to claim 7, wherein the at least one concave stria and the at least one convex stria are interlaced.

11. The light-emitting diode according to claim 7, wherein the at least one concave stria and the at least one convex stria are symmetrically distributed in the surface of the package structure.

12. The light-emitting diode according to claim 7, wherein the at least one concave stria and the at least one convex stria are asymmetrically distributed in the surface of the package structure.

13. A light-emitting diode, comprising:
a light-emitting diode chip having a first light shape; and
a package structure covering the light-emitting diode chip, wherein a surface of the package structure has a pattern structure, and the pattern structure includes at least one convex stria for transforming the first light shape of the light-emitting diode chip into a second light shape to control a light shape output by the light-emitting diode.

14. The light-emitting diode according to claim 13, wherein a material of the package structure is selected from the group consisting of epoxy, silicone and glass.

15. The light-emitting diode according to claim 13, wherein a section of the at least one convex stria is a curve or a polygonal curve.

16. A light-emitting diode, comprising:
a light-emitting diode chip; and
a package structure covering the light-emitting diode chip, wherein a surface of the package structure has a pattern structure, and the pattern structure includes a plurality of stria structures for controlling a light shape output by the light-emitting diode.

17. The light-emitting diode according to claim 16, wherein the stria structures are a plurality of concave strias and/or a plurality of convex strias.

18. The light-emitting diode according to claim 16, wherein a section of each stria structure is a curve or a polygonal curve.

19. The light-emitting diode according to claim 16, wherein the stria structures are substantially parallel.

20. The light-emitting diode according to claim 16, wherein the stria structures are interlaced.

21. The light-emitting diode according to claim 16, wherein the stria structures are symmetrically distributed in the surface of the package structure.

22. The light-emitting diode according to claim 16, wherein the stria structures are asymmetrically distributed in the surface of the package structure.

23. The light-emitting diode according to claim 16, wherein a material of the package structure is selected from the group consisting of epoxy, silicone and glass.
